(19) United States
(12) Patent Application Publication
(10) Pub. No.: US 2004/0201502 A1
(43) Pub. Date: Oct. 14, 2004

(54) Alphanumeric character layouts for input devices

(76) Inventor: Kwok Chung Wong, Alhambra, CA (US)

Correspondence Address: INTELLECTUAL PROPERTY LAW GROUP LLP, 12 SOUTH FIRST STREET, SUITE 1205, SAN JOSE, CA, 95113, US

(21) Appl. No.: 10/396,925

(22) Filed: Apr. 14, 2003

(51) Int. Cl. H03M 11/00; H03K 17/94

(52) U.S. Cl. 341/22

(57) ABSTRACT

An embodiment of the present invention discloses a method and apparatus for arranging alphanumeric characters on an input device according to their similarity to Arabic numerals. These similarities are visibly apparent and recognizable patterns, which makes the arrangement user-friendly and promotes ease of learning and improved retention of alphanumeric key layout. In other embodiments of the present invention, Greek and Russian characters are arranged on an input device in a layout also in accordance with similarity to Arabic numerals. Embodiments of the present invention also disclose an ergonomic input device which implements the layout of characters according to similarity to numerals.

### BACKGROUND OF THE INVENTION

1. Field of the Invention

The present invention relates to the arrangement of alphanumeric keys on input devices used for typing, indexing, optical reading, inputting characters from other writing systems, even mathematics and computer programming. This novel arrangement is based on the letters' similarity to the ten Arabic numerals. Using this alphanumeric arrangement, anyone can identify a letter's location intuitively, without relying heavily on memorization of a letters' location on a keyboard.

The layout of the keys on a standard keyboard is commonly referred to as QWERTY. The name for the arrangement derives itself from the first six letters on the top row of a standard keyboard found on such devices as a typewriter or computer keyboard. Since its introduction over 100 years ago, QWERTY remains the standard format on nearly every keyboard used throughout the world. QWERTY remains a keyboarding mainstay more because it was one of the first widely distributed keyboard arrangements, rather than possession of a superior layout.

Perhaps the most well known alternative to QWERTY is the Dvorak layout. Professor August Dvorak sought a letter arrangement on a keyboard that would improve a typist's speed, accuracy, and ease of use. The resulting Dvorak arrangement was the result of his research and studies into replacing QWERTY with a scientifically devised layout. Based on numerous tests run by Dvorak, himself, he claimed the Dvorak layout superior to the QWERTY. However, despite his claims of increased typing speed, most independent experiments have found little, if any, difference in speed between the two keyboard layouts. The widespread use of QWERTY and the lack of definitive advantages of the Dvorak layout meant that the Dvorak layout never replaced QWERTY, which remains the mainstay of keyboard layouts.

Another reason QWERTY remains the dominant keyboard layout stems from the difficulty in learning a new keyboard arrangement. After memorizing and familiarizing oneself with the random locations of keys on a QWERTY keyboard, few people desire to do the same for an entirely different system.

For the foregoing reasons, a new layout of keyboard is necessary. One that improves a typist's efficiency while at the same time having the added advantage of being relatively easy to learn and use.

### SUMMARY OF THE INVENTION

An embodiment of the present invention arranges alphanumeric characters on an input device according to their similarity to Arabic numerals. A numerical based system can help people easily learn the alphabet. Usually, people learn the alphabet by reciting the entire sequence of letters. The list has even been turned into a song to help people learn the alphabet. While learning the sequence of the alphabet allows one to know the letters, it is not the best method for learning the locations of the letters. Since the alphabet is learned as a list, people often recite the whole list to find the location of a specific letter.

To speed up the process of locating a letter, assigning a number to a letter would be a quicker method for knowing the exact location of a letter. Assigning a numerical system to the alphabet has the advantage of helping people learn the alphabet more easily, locate keys on an input device, and improve typing skills.

Since the alphabet is a sequence, a number could be assigned to a letter based on its position within the sequence. For example, A is number 1, B is number 2, and Z is number 26. Such a system is easy for locating letters at the beginning or end of the alphabet, but it becomes more difficult when asked what number represents a letter in the middle of the alphabet. Although, the alphabet is not a series of numerical figures, the letters themselves have features that are similar to numerical characters. An improved system assigns numerical values to letters of the alphabet based on visual similarities between them.

The preferred embodiment of the present invention arranges the alphanumeric characters on an input device in a numerical order, and a systematical visual array, which is easy to learn, remember, and efficient to use. The embodiment of the present invention assigns a numerical value to letters based on a letter's similarity to a numeral. These similarities are visibly apparent and recognizable patterns, which makes the arrangement user-friendly and promotes ease of learning and improved retention of alphanumeric key layout. The embodiment of the present invention allows people to distinguish any letter's position by intuition instead of completely relying on memorization of the arrangement of the keys.

An embodiment of the present invention first assigns a unique number to each of the 26 letters and 10 numerals. The number characters 0-9 look identical to the numbers 0-9 and are consequently assigned those numbers. Next, the 26 letters are separated into groups, with each group comprising a series of letters that appear similar to the Arabic numerals 0-9. For those few characters that do not look like a number, there value is assigned based on the letter's connection to a number, such as the letter V being assigned the value 5 because it looks like the Roman numeral for five.

The embodiments of the present invention provide a numbering scheme of letters that is applicable to the alphanumeric keys on a keyboard. Each row of letters on the keyboard is arranged according to the letter groupings. If we arrange the 26 letters in this way: the numbers 0-9 become the top row of alphanumeric keys, DHRMFKGLBP becomes the second, QJZWXVCTSN the third, and OIUEAY are in the fourth row. This arrangement provides a logical arrangement of alphanumeric keys based on the sequence of their numerical equivalents.

An additional embodiment can take into account the frequency of use for the letters within the letter groups as well as keys for commonly used punctuation marks. In one embodiment, punctuation marks are placed on keys within the rows of letters and eight of the 10 top high frequency alphanumeric characters are allocated to the home row keys on a keyboard.

In another embodiment, the letters are arranged to take into account the striking finger. This allows a user's stronger index, middle, and ring fingers to strike the keys of more frequently used letters, leaving the weaker pinkie finger to strike the keys of lesser-used letters. Also, less frequently used keys are not placed in the home row.

In yet another embodiment of this invention, Roman letters are substituted for the letters of other writing systems. For example, a keyboard input device may organizes Greek letters into groups according to their likeness to the ten Arabic numbers

In a further embodiment of this invention, Russian letters are substituted for the letters of other writing systems. For example, a keyboard input device may organize Russian letters into groups according to their likeness to the ten Arabic numbers.

These and other embodiments of the present invention are further made apparent, in the remainder of the present document, to those of ordinary skill in the art.

### BRIEF DESCRIPTION OF THE DRAWINGS

In order to more fully describe embodiments of the present invention, reference is made to the accompanying drawings. These drawings are not to be considered limitations in the scope of the invention, but are merely illustrative.

FIG. 1 uses the numerical values assigned to letters to indicate the placement of alphanumeric keys on an input device according to an embodiment of the present invention.

FIG. 2 shows the arrangement of alphanumeric keys according to FIG. 1 as applied to a standard computer keyboard according to an embodiment of the present invention.

FIG. 3 provides another arrangement of alphanumeric keys indicating the location of the keys based on their numerical equivalent according to an embodiment of the present invention.

FIG. 4 depicts the arrangement of alphanumeric keys according to FIG. 3 as applied to a standard computer keyboard according to an embodiment of the present invention.

FIG. 5 depicts another arrangement of an input device by using the traditional order of letters in an ergonomic keyboard according to an embodiment of the present invention.

FIG. 6 depicts another arrangement of an input device for a right-handed person, based on the embodiment shown in FIG. 5 in reverse sequence.

FIG. 7 depicts another arrangement of an input device derived from FIGS. 5 and 6, according to an embodiment of the present invention.

FIG. 8 illustrates an adjusted input device layout according to an ergonomic placement of the user's fingers, based on FIGS. 5, 6 and 7 according to an embodiment of the present invention.

FIG. 9 shows the vertical section view of the differing thickness of each key in a column according to an embodiment of the present invention.

FIG. 10 illustrates another layout of an input device containing both Arabic and Greek alphanumeric keys according to an embodiment of the present invention.

FIG. 11 illustrates another layout of an input device containing Russian alphanumeric characters according to an embodiment of the present invention.

### DETAILED DESCRIPTION OF THE INVENTION

The description above and below and the drawings of the present document focus on one or more currently preferred embodiments of the present invention and also describe some exemplary optional features and/or alternative embodiments. The description and drawings are for the purpose of illustration and not limitation. Those of ordinary skill in the art would recognize variations, modifications, and alternatives. Such variations, modifications, and alternatives are also within the scope of the present invention. Section titles are terse and are for convenience only.

The present invention is described as an arrangement of the alphanumeric keys found on a keyboard. The invention is applicable to any device employing an alphanumeric keypad for input such as a computer, typewriter, personal digital assistant, and calculator.

The embodiment of the present invention first assigns a unique number to each of the 26 letters and 10 numerals. The number characters 0-9 look identical to the numbers 0-9 and are consequently assigned those numbers. Next, the 26 letters are separated into groups, with each group comprising a series of letters that appear similar to the Arabic numerals 0-9. For those few characters that do not look like a number, there value is assigned based on the letter's connection to a number, such as the letter V being assigned the value 5 because it looks like the Roman numeral for five.

In assigning values to the alphanumeric keys, the numbers 0-9 are assigned a value of 0-9. Next, the alphabet can be broken down into three groupings of letters. In looking at the first group, with the exception of G, the letters DHRMFKGLBP all have a vertical left stroke. This vertical stroke looks similar to a 1 and thus all these letters will be assigned a number from 10-19. The table below indicates the letter, its numerical equivalent, and reasoning for the assignment.

| Letter | Reason for Assignment of Numerical Value | Value |
|---|---|---|
| D | It looks similar to 0. | 10 |
| H | It has two vertical strokes which look like two 1s. | 11 |
| R | The right hand side of the R looks similar to the rounded | 12 |
| | side and bottom of a 2. | |
| M | Rotate M 90 clockwise and it looks like 3. | 13 |
| F | Rotate the letter 90° counter-clockwise and it looks | 14 |
| | similar to a 4. Moreover, four is spelled with an F. | |
| K | Rotating the last two strokes 90° counter-clockwise | 15 |
| | looks like the Roman numeral for the number 5. | |
| G | It has a similar shape to 6. | 16 |
| L | By rotating the letter counter-clockwise 180° it looks like 7. | 17 |
| B | The right edge of the letter looks like the right edge of the | 18 |
| | number 8. | |
| P | It looks like a 9 reflected across a vertical axis. | 19 |

The next group of letters is OIUEAYCTSN. This group, with the exception of Y and N also look similar to the Arabic numbers 0-9. Since this is the second group of letters, this group will begin with 2.

| Letter | Reason for Assignment of Numerical Value | Value |
|---|---|---|
| O | It looks similar to 0. | 20 |
| I | It looks similar to 1. | 21 |
| U | Rotate U 900 counter-clockwise and its rounded like 2. | 22 |
| E | The letter E reflected across a vertical axis like 3. | 23 |
| A | Rotate clockwise 45° and remove the bottom portion | 24 |
| | of the left leg and it looks like 4. | |
| Y | Its upper two strokes make a vee shape like the Roman | 25 |
| | character 5. | |
| C | The letter has a similar curving shape like 6. | 26 |
| T | Remove the right hand side of the top bar and it looks | 27 |
| | like a 7. | |
| S | It looks similar to 8. | 28 |
| N | It is the first letter when writing nine. | 29 |

The remaining 6 letters QJZWXV are also assigned a numerical value. The third series of letters resemble the numbers 0-5 and are assigned numerical values of 30-35, respectively.

| Letter | Reason for Assignment of Numerical Value | Value |
|---|---|---|
| Q | It looks like 0. | 30 |
| J | It looks like 1. | 31 |
| Z | It looks like 2. | 32 |
| W | If you turn W 90° counter-clockwise, it looks like 3. | 33 |
| X | X and 4, both have crossing strokes. Also, it is | 34 |
| | the Chinese numerical character 4. | |
| V | It looks like the Roman numeral for 5. | 35 |

In addition to Roman letters and numbers, this assignment system can also be applied to other letters systems. Consequently, another embodiment of this invention allows Roman letters to be substituted for the letters of other writing systems. For example, the invention also covers a keyboard input device that organizes the 24 Greek letters into three groups according to their likeness to the 10 Arabic numbers. Since input devices are often arranged in rows of ten, first separate the Greek letters into groups of ten. The first group of ten letters, ΘψZΣXΛΔT [symbol] N looks almost like the 10 Arabic numerals, 0123456789, respectively. The second group of 10 letters is ΦHΠMAKYΓBP. This group of letters is another group of letters and so they are also assigned a two-digit number. The remaining 4 vowels OIΩE are also given a two-digit numerical value number. Based on this grouping, all the letters became a series of sequential numbers as follow:

ΘψZΣXΛΔ [symbol] N

ΦHΠMAKYΓBP

OIΩE

Furthermore, the Roman letters can also be substituted with other letters systems, such as Chinese, Japanese, Russian, and so on. For example, an embodiment of the invention also covers a keyboard input device that organizes the 33 Russian letters into four groups according to their likeness to the ten Arabic numbers. Initially separate the Russian letters into groups of ten. The first group of ten letters [symbol] [symbol] looks similar to the ten Arabic numerals, 0123456789, respectively. The second and third group of ten letters is [symbol] [symbol] and [symbol] [symbol] which also resemble the ten Arabic numeral numbers, and the last 3 letters [symbol] resemble the Arabic number 3 as well.

These letters could be placed on a input device by themselves, or make up additional rows on an input device that already contains Roman letters.

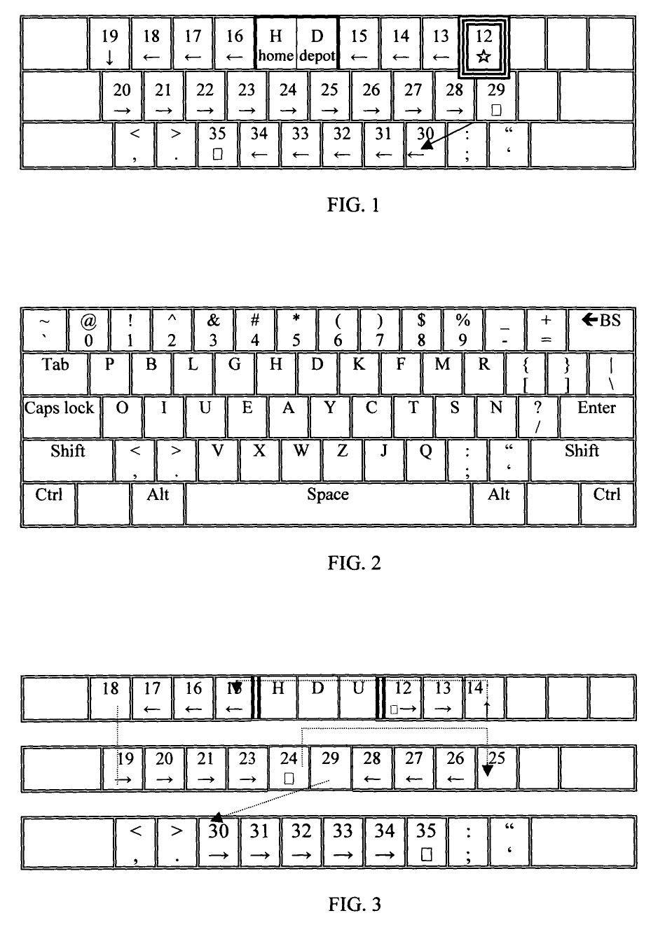

In one embodiment of the present invention, letters H and D are the fifth and sixth letter keys in the top row containing letters. The remaining alphabet characters are allocated to the keyboard sequentially according to their assigned numerical value. The overall arrangement of the letters is an ‘S’ shape configuration based on the numerical value of the letters. FIG. 1. shows the numerical arrangement for the letters on a possible input device. FIG. 2 shows the application of the arrangement of letters based on the order from FIG. 1 for a standard computer keyboard; complete with numeral keys, and secondary keys such as “shift”, a spacebar, and other keys typically found on keyboard input devices.

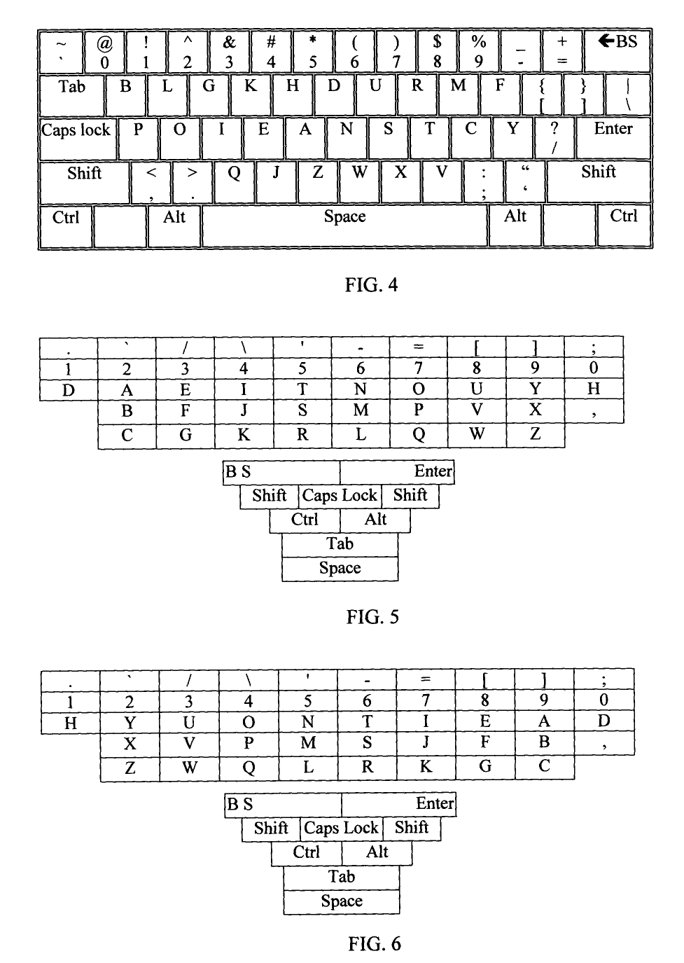

FIG. 3 depicts another embodiment of the present invention where letters H, D, and U are the fifth, sixth, and seventh keys of the upper row letter keys. The remaining letter keys are arranged according to the numerical sequence in FIG. 3. FIG. 4 shows the arrangement of FIG. 3 being applied to a standard computer keyboard.

FIG. 5 discloses yet another embodiment for the layout of a keyboard utilizing the traditional order of letters in an ergonomic arrangement. This embodiment contains an upper and lower two parts. The upper part is in an array of five rows of ten columns. The lower part has five rows. The alphanumeric characters are allocated to the upper part and function keys are allocated to the middle of the lower part. Letters D and H are arranged in the third row in column 1 and column 10 respectively. This row is also called the home row. The remaining 24 letters are separated into eight sequential groups allocated to the three lower rows of the upper part, respectively. These eight groups are: ABC,EFG, IJK, RST, LMN, OPQ, UVW and XYZ, with the vowel, semi-vowel and two high frequency letters T and N in the home row, respectively. FIG. 6 shows a reverse sequential layout of the embodiment of FIG. 5 for a right-handed person.

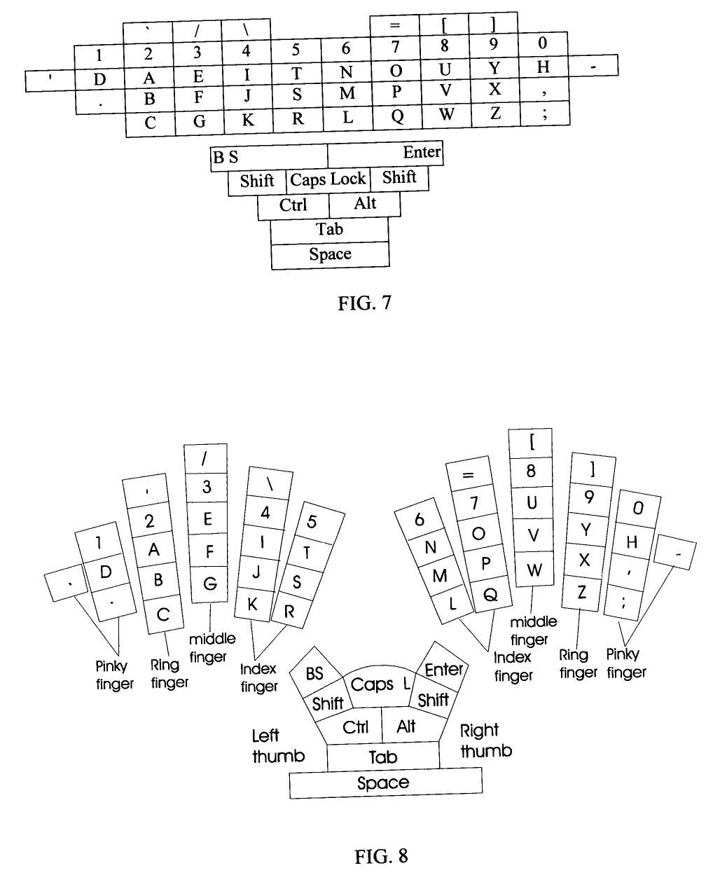

FIG. 7 illustrates yet another embodiment for the layout of a keyboard derived from FIG. 5 by moving four of the punctuation marks from the uppermost row to the position of the pinky finger operated area. In particular, the ‘key is moved from the uppermost row to the third row before D and the—key is moved to the third row next to H. Furthermore, the key is moved from the uppermost row to the fourth key of the same column and the; key is moved from the uppermost key to the fifth key of the same column.

FIG. 8 shows an adjusted layout of FIGS. 5, 6 and 7 according to an ergonomic layout adapted to a user's fingers as another embodiment of the present invention. The columns are rotated both in the left and right direction and keys are positioned upward or downward to suit the user's finger placement on the keyboard.

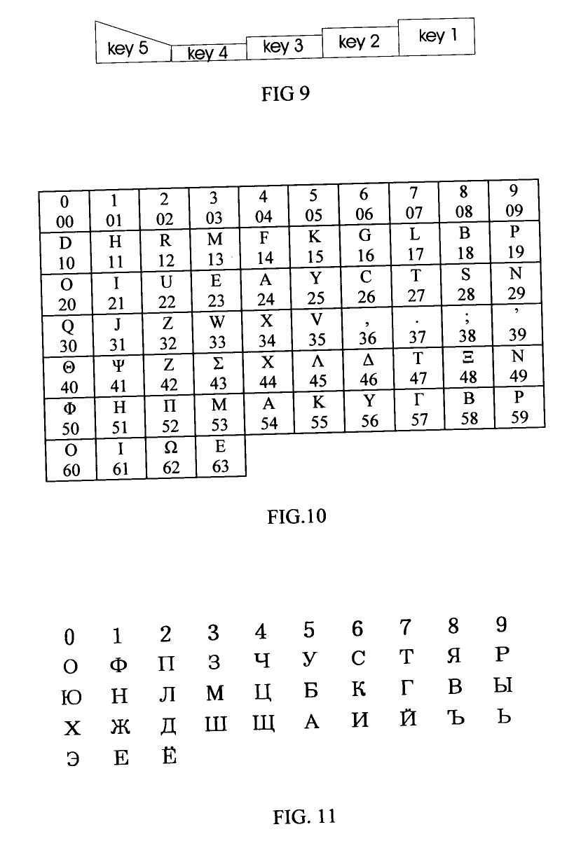

FIG. 9 illustrates the layout of a vertical section view which shows the differing thickness of each key in the column in an embodiment of the present invention.

The previous embodiments relate to standard keyboards, however, this system of arranging letters is not limited to Roman letters or a standard keyboard. FIG. 10 shows a possible layout of an input device with both Arabic and Greek letters.

In yet another embodiment of the present invention, the layout of an input device may comprise Russian letters. FIG. 11 shows such an arrangement of Russian letters.

The previous disclosure and description of the invention provides a detailed description of the embodiment of the present invention. However, these embodiments are illustrative rather than restrictive, indicating that the invention may be present in several alternative embodiments without departing from the essence of the invention. It is especially understood that the inventive aspects relate to the arrangement of the alphanumeric keys and alterations in the design of the input device and arrangement of function keys such as ‘shift’, ‘caps lock’, punctuation, and the like are not limitations on the present invention.

Throughout the description and drawings, example embodiments are given with reference to specific configurations. It will be appreciated by those of ordinary skill in the art that the present invention can be embodied in other specific forms. Those of ordinary skill in the art would be able to practice such other embodiments without undue experimentation. The scope of the present invention, for the purpose of the present patent document, is not limited merely to the specific example embodiments of the foregoing description, but rather is indicated by the appended claims. All changes that come within the meaning and range of equivalents within the claims are intended to be considered as being embraced within the spirit and scope of the claims.

What is claimed is:

1. A method for arrangement of letter and number characters on keys of an input device comprising:
dividing letter and number characters into a plurality of groups;
assigning a number value to each letter and number character in said groups based on a character's structural similarity to a number or some other similarity between the character and a number; and
arranging said letter and number characters to a plurality of keys on an input device based on the number value assigned to each character.

2. An input device having a plurality of keys arranged in rows, and having characters assigned to at least some of the plurality of keys, and having said characters assigned a numerical value, wherein
an order of characters on a top row of keys is determined by arranging said characters in a series from according to an incremental decrease in the numerical value of a character from the numerical value of a previous character assigned to said top row;
an order of characters on a row directly below said top row whose order of characters is determined by arranging the characters in a series according to an incremental increase in the numerical value of a character from the numerical value of a previous character assigned to said row; and
an order of characters on a bottom row directly below a previous row whose order of characters is determined by arranging the characters in a series according to an incremental decrease in the numerical value of a character from the numerical value of a previous character assigned to said bottom row.

3. The input device according to claim 2, having said top row of keys determined by arranging the characters in a series according to an incremental decrease in the numerical value of a character from the numerical value of the previous character assigned to said top row; and
wherein letters H and D are middle characters in the series, and the numerical value of letters H and D is not considered when arranging an order of said keys in said top row.

4. The input device according to claim 2, having an arrangement of characters on some of the keys comprising:
a top row of keys assigned characters P B L G H D K F M R;
a row of keys below said top row assigned characters O I U E A Y C T S N; and
a bottom row of keys two rows below said top row assigned characters V X W Z J Q.

5. An input device having a plurality of keys arranged in rows, and having alphanumeric characters assigned to at least some of the keys, and having said alphanumeric characters assigned a numerical value, wherein:
an order of characters on a top row of keys is determined by assigning a character to each of said top row of keys on a left half of the top row according to an incremental decrease in the numerical value of a character from left to right, and assigning a character to each of said top row of keys on a right half of the top row according to an incremental increase in the numerical value of a character from left to right; and
an order of characters on a row of keys directly below said top row is determined by assigning a character to each of said row keys on a left half of the row according to an incremental increase in the numerical value of a character from left to right, and assigning a character to each of said row keys on a right half of the row according to an incremental decrease in the numerical value of a character from left to right; and
an order of characters on a bottom row of keys directly below the previous row of keys is determined by assigning a character to each of said bottom row keys according to an incremental increase in the numerical value of a character from left to right.

6. The input device according to claim 5, wherein the top row of keys has letters H D U as middle characters separating said left half and right half of the top row;
wherein the numerical value of letters H D U is not considered when arranging the order of said keys in the top row.

7. The input device according to claim 5, having an arrangement of characters on some of the keys comprising:
a top row of keys having characters B L G K H D U R M F;
a row of keys below said top row having characters P O I E A N S T C Y; and
a bottom row of keys positioned two rows below said top row having characters Q J Z W X V.

8. An input device having a plurality of keys comprising
an upper section of keys arranged essentially in a plurality of columns, and a lower section of keys;
wherein said upper section of keys are assigned a plurality of characters and said lower section of keys are assigned a plurality of function keys.

9. The input device according to claim 8, wherein the upper section of keys forms an array of ten columns and a number of rows of keys, and
a first row of keys are assigned a plurality of punctuation marks;
a second row of keys are assigned a plurality of numerical characters; a lower
three rows of keys having letters assigned to at least some of the keys;
a third row of keys is a home row having home row keys; and
wherein the lower section of keys comprise five rows of function keys.

10. The input device according to claim 9, further comprising:
a letter D assigned to the home row in a first column;
a letter H assigned to the home row in a tenth column;
a number of sequential letter groupings of ABC, EFG, IJK, RST LMN, OPQ UVW and XYZ arranged in columns in said lower three rows of keys, whereby letters increase in an alphabetic sequence from letter A to letter Z, wherein grouping ABC is arranged in an increasing sequence in a second column with letter A is in the home row;
grouping EFG is arranged in an increasing sequence in a third column with letter E in the home row;
grouping IJK is arranged in an increasing sequence in a fourth column with letter I in the home row;
grouping RST is arranged in a decreasing sequence in a fifth column with letter T in the home row;
grouping LMN is arranged in a decreasing sequence in a sixth column with letter N in the home row;
grouping OPQ is arranged in an increasing sequence in a seventh column with letter O in the home row;
grouping UVW is arranged in an increasing sequence in an eighth column with letter U in the home row;
grouping XYZ is arranged in a column 9 with letter Y in the home row and letters X and Z in an increasing sequence thereafter.

11. The input device according to claim 10, wherein the lower section keys further comprise:
a first row having a left key assigned a Back Space function and a right key assigned an Enter function;
a second row having a left key and a right key assigned a Shift function and a middle key assigned a Caps Lock function;
a third row having a left key assigned a Ctrl function and a right key assigned a Alt function;
a fourth row having a key assigned a Tab function; and
a fifth row having a key assigned a Space function.

12. The input device according to claim 10, further comprising:
a zero column and an eleventh column wherein a punctuation key is assigned to each of the home row keys in the zero column and the eleventh column;
a punctuation key assigned to a fourth row key in the first column and the tenth column;
a punctuation key assigned to a fifth row key in the first column or the tenth column.

13. The input device according to claim 12 wherein
a ‘ key is assigned to the home row key in the zero column
a - key is assigned to the home row key in the eleventh column,
a . key is assigned the fourth row key in the first column,
a , key is assigned to the fourth row key in the tenth column,
a ; key is assigned to the fifth row key in the first column or the tenth column.

14. The input device according to claim 11, further comprising:
a zero column and an eleventh column wherein a punctuation key is assigned to each of the home row keys in the zero column and the eleventh column;
a punctuation key assigned to a fourth row key in the first column and the tenth column;
a punctuation key assigned to a fifth row key in the first column or the tenth column.

15. The input device according to claim 12, wherein the arrangement of the columns and rows are ergonomically positioned to adapt to a user's hands whereby keys in the zero through fifth columns of the upper section of keys are spaced apart from keys in the sixth through eleventh columns forming a first hand set and a second hand set, wherein
the columns and rows of the first hand set and the second hand set are positioned in a curved manner to resemble a user's fingers;
the fourth and fifth columns of the first hand set and the sixth and seventh columns of the second hand set are positioned to slant toward a middle of the input device;
the zero, first and second columns of the first hand set and the ninth, tenth and eleventh columns of the second hand set are positioned to slant away from the middle of the input device.

16. The input device according to claim 14, wherein the arrangement of the columns and rows are ergonomically positioned to adapt to a user's hands whereby keys in the zero through fifth columns of the upper section of keys are spaced apart from keys in the sixth through eleventh columns forming a first hand set and a second hand set, wherein
the columns and rows of the first hand set and the second hand set are positioned in a curved manner to resemble a user's fingers;
the fourth and fifth columns of the first hand set and the sixth and seventh columns of the second hand set are positioned to slant toward a middle of the input device;
the zero, first and second columns of the first hand set and the ninth, tenth and eleventh columns of the second hand set are positioned to slant away from the middle of the input device.

17. An input device having a plurality of keys arranged in rows, and having characters assigned to at least some of the keys, and having said characters assigned a numerical value, wherein
a plurality of Arabic letter characters are arranged on a top row of letter keys, on a second row of letter keys below the top row, and on a third row of letter keys below the second row;
a plurality of Greek letter characters are arranged on a fourth row of letter keys below the third row, on a fifth row of letter keys below the fourth row, and on a sixth row of letter keys below the fifth row;
wherein an order of each row of letter keys is determined by assigning one of a series of characters to each key, according to an incremental increase in the numerical value assigned to a character from left to right and beginning from said top row, and each character in each subsequent row increasing in numerical value over each character in a previous row.

18. The input device according to claim 17, having an arrangement of characters on some of the keys comprising:
the top row of keys having characters D H R M F K G L B P;
the second row of keys having characters O I U E A Y C T S N;
the third row of keys having characters Q J Z W X V , . ; ‘;
the fourth row of keys having characters Θ ψ Z Σ X Λ Δ T [symbol] N;
the fifth row of keys having characters Φ H Π M A K Y Γ B P; and
the sixth row of keys having characters O I Ω E.

19. An input device having a plurality of keys arranged in rows, and having characters assigned to at least some of the keys, and having said characters assigned a numerical value, wherein
a plurality of numerical characters are arranged on a top row of keys,
a plurality of Russian letter characters are arranged on a second row of letter keys below the top row, on a third row of letter keys below the second row, and on a fourth row of letter keys below the third row,
wherein an order of each row of letter keys is determined by assigning one of a series of characters to each key, according to an incremental increase in the numerical value assigned to a character from left to right.

20. The input device according to claim 19, having an arrangement of characters on some of the keys further comprising:
the top row of keys having characters 0 1 2 3 4 5 6 7 8 9;
the second row of letter keys having characters [symbol] [symbol] ;
the third row of letter keys having characters [symbol] [symbol] ;
the fourth row of letter keys having characters [symbol] [symbol] ; and
a fifth row of letter keys below the fourth row having characters [symbol] .
